(19) United States
(12) Patent Application Publication
(10) Pub. No.: US 2025/0299982 A1
(43) Pub. Date: Sep. 25, 2025

(54) METHOD AND DEVICE FOR POST-PROCESSING OF ENCAPSULATED INTEGRATED CIRCUITS

(71) Applicant: TFA EUROPE B.V., 's-Heerenberg (NL)

(72) Inventors: Hubert Wilhelm Petrus CLAASSEN, 's-Heerenberg (NL); Frans Joseph DERKSEN, 's-Heerenberg (NL); Erik BROUWER, 's-Heerenberg (NL)

(21) Appl. No.: 18/863,459

(22) PCT Filed: May 8, 2023
(86) PCT No.: PCT/EP2023/062116

§ 371 Date: Nov. 6, 2024

(30) Foreign Application Priority Data
May 9, 2022 (NL) 2031798
May 9, 2022 (NL) 2031799

(51) Int. Cl. H01L 21/67; H01L 21/48; H01L 21/677

(52) U.S. Cl. CPC H01L 21/67092; H01L 21/4842; H01L 21/6773; H01L 21/67736; H01L 21/67742

(57) ABSTRACT

The present invention relates to a device for post-processing encapsulated integrated circuits, comprising a transit line, extending from an input location along at least one post-processing device for post-processing encapsulated integrated circuits to an output location, at least a first carrier independently movable across the transit line equipped for moving the encapsulated integrated circuits across the transit line between a first receipt location on the transit line and a first release location on the transit line, and at least one second carrier independently movable across the transit line, equipped for moving the encapsulated integrated circuits across the transit line between a second receipt location on the transit line and a second release location on the transit line.

The present invention relates to a method and device for post-processing of encapsulated integrated circuits (ICs). Integrated circuits in this context mean electronic circuits that often comprise a silicon chip. Such chips are manufactured on a so-called wafer, where they are then cut out and the external electrical contact points located on them are connected to terminal pins, which are currently held together as they are collectively and interconnected in a frame. After making the electrical connections between the external electrical contact points and terminal pins, an enclosure is fitted around the chip and the electrical connections to protect them. Next, the integrated circuits need to be post-processed. This post-processing involves, for example, removing interconnections between pins for the purpose of the manufacturing process, bending the pins (in most cases) and detaching the integrated circuit from its surrounding frame. Such a frame is called a lead frame and it is common for such a frame to comprise several integrated circuits, often even a (quasi-) infinite number, so that the integrated circuits can be routed along further post-processing steps in an interconnection determined by the frame. Thereby, all integrated circuits follow the same path along various post-processing steps, often in the same order and with the same processing speed or rhythm. A processing rhythm here refers to a stepwise throughput, in which all integrated circuits move one position further when one of the circuits has progressed a certain post-processing step. An example of such a system, where all integrated circuits follow the same path along various post-processing steps, in the same order and at the same processing speed or rhythm, is given by US patent publication U.S. Pat. No. 5,494,149A. As a result, it does not have at least one transfer device, for taking off an encapsulated integrated circuit at the first delivery location of the first carrier, feeding the encapsulated electrical circuit through the first post-processing device feeding and delivering the encapsulated integrated circuit to the second carrier at the second receipt location. The same goes for Korean patent publication KR20030063837Al.

Among other things, this has the disadvantage that the throughput is determined by the longest lasting post-processing step but also that there is no flexibility in letting the post-processing steps that various integrated circuits go through and the movements they make in the process differ because they are limited relative to each other by the fact that the integrated circuits are mechanically coupled to each other. Also, the number of movements and hence post-processing operations that an integrated circuit can undergo is limited by the fixed mutual orientation imposed by the interlocking of multiple integrated circuits. When the integrated circuits comprise power electronics, i.e., electronics intended for conducting large currents (several amperes or more) or handling large voltages (tens of Volts), the circuits, their housings and their connections are correspondingly larger and, in addition to the already mentioned drawbacks to the state of the art, their post-processing also becomes a more complex affair, which cannot be carried out, or cannot be carried out without further drawbacks, with the existing devices and working methods. Such integrated circuits may also be referred to as “components” in the following.

The larger circuits not only have a larger housing, but also thicker and longer connecting pins, which, if they have to be bent over, also lead to additional height gain.

Therefore, a further drawback to the existing methods and devices for post-processing of encapsulated integrated circuits is that the ability to carry out monitoring and inspection is hampered by the overall structure, where the integrated circuits to be post-processed are largely in contiguous post-processing equipment.

It is therefore an object of the present invention to provide a device and method for post-processing of encapsulated integrated circuits, in particular encapsulated integrated circuits of power electronics, such as those for use in electric cars.

For this purpose, the invention proposes a device for post-processing already encapsulated integrated circuits, comprising a transit line, extending from an input location along at least one post-processing device for post-processing encapsulated integrated circuits to an output location, at least a first carrier independently movable from a second carrier across the transit line arranged to move the encapsulated integrated circuits across the transit line between a first receipt location on the transit line and a first release location on the transit line, at least the second carrier independently movable from the first carrier across the transit line arranged to move the encapsulated integrated circuits across the transit line between a second receipt location on the transit line and a second release location on the transit line, where preferably the first release location and the second receipt location are at least substantially coincident; wherein the first release location and the second receipt location are at least substantially coincident, at least one finishing device, at the level of the first release location and selected from the group comprising a punching or trimming device for shortening connecting pins of the integrated circuit, a bending device for bending connecting pins of the integrated circuit or a punching device for removing a lead frame of the integrated circuit and at least one transfer device, for taking an encapsulated integrated circuit from the first carrier at the first release location and passing the encapsulated electrical circuit through the first post-processing device and releasing the encapsulated integrated circuit to the second carrier at the second receipt location.

Where the devices according to the prior art carry the encapsulated integrated circuits on a carrier for continuous or incremental transit past or through finishing devices, whether or not jointly on lead frames, the device according to the present invention provides by the first and second carriers making a shuttle movement that is, a reciprocating movement, in which the integrated circuits are removed from the first carrier by a transfer device for the purpose of a post-processing step and, after undergoing the post-processing step, are placed on the second carrier, the possibility of the first and second carriers moving at different speeds and moments. The first and second carriers are mutually independent so that they can each operate at an optimal speed, with one being able to move continuously and the other incrementally, for example. As a result, there is less delay in the process. In addition, this construction makes the length and/or number of post-processing steps in the facility unlimited and allows a carrier to return to its respective receipt location. Also, the device according to the invention makes it possible for certain encapsulated integrated circuits to skip certain post-processing steps if those processing steps are not required for those encapsulated integrated circuits, thus increasing the average throughput speed.

In a preferred embodiment, the first and second carriers are arranged for moving one encapsulated integrated circuit each. To this end, the first and second carriers are matched in size to that of an integrated circuit to be moved. The apparatus according to the invention is (thereby) also arranged for the piece-by-piece feeding and post-processing of encapsulated integrated circuits.

Preferably, the first carrier shuttles or commutes or is configured to shuttle or commute between a first receipt location on the transit line and a first release location on the transit line and, further preferably, the second carrier shuttles or commutes or is configured to shuttle or commute between a second receipt location on the transit line and a second release location on the transit line. That is, the first carrier moves back and forth the in opposite directions across the transit line back from the first release location to the receipt release location when the encapsulated electronic circuit has been taken over by the transfer device. Preferably, the second carrier moves in the opposite direction along the transit line back from the second release location to the second receipt location. Where commuting is mentioned in this application, “arranged to commute” should also be understood and commuting back and forth may be called to shuttle.

When several different finishing steps are to be carried out, the device according to the invention further comprises at least a third carrier independently movable from the first and second carrier over the transit line, for moving the encapsulated integrated circuits over the transit line between a third receipt location on the transit line and a third release location on the transit line where the second release location and the third receipt location are at least substantially coincident. A second finishing device, at the level of the second receipt location and selected from the group consisting of a punching or trimming device for shortening connecting pins of the integrated circuit, a bending device for bending connecting pins of the integrated circuit or a punching device for removing a lead frame of the integrated circuit a second transfer device, for taking an encapsulated integrated circuit from the second carrier at the second release location, passing the encapsulated electrical circuit through the second post-processing device; and delivering an encapsulated integrated circuit to the third carrier at the third receipt location. Therein, the second post-processing device may preferably be different from the first post-processing device. When more than two post-processing devices are required, the device according to the invention may be further extended in a similar manner to comprise a fourth carrier and a third post-processing device according to the invention.

The device according to the invention can also be cascaded with a similar or identical device. That is, the transit lines of the two (or further) devices are placed adjacent and in line with each other and post-process the same lead frame and/or component subsequently, or are configured thereto.

The device according to the invention may further comprise an infeed device, in particular a gripper movable by means of a robotic arm, for gripping at the infeed location and feeding to the device an integrated circuit to be machined from a housing to be machined. The use of such a robotic arm enables the removal of integrated circuits from a rack or other type of infeed holder after finishing. Further, the device may comprise an output device, for outputting at the output location from the device a finished encapsulated integrated circuit.

In a further embodiment, a product carrier tray attached to or integral with at least one of the carriers comprises a product carrier tray, which tray is provided with a spacer for carrying an encapsulated integrated circuit remotely from a carrier surface such that it is grippable on at least one side at top and bottom for an input, output, or transfer device.

The first, second or further carrier may be further arranged for carrying the encapsulated integrated circuit to a lead frame thereof.

In a further embodiment, the facility according to the invention may be arranged for sorting out punching or trimming waste. This punching or trimming waste is mostly copper or otherwise made up of conductor material connecting or (lead) frame parts that can be recycled.

In order to achieve sufficiently fast and accurate positioning of the integrated circuits, the transit line may comprise a linear motor. More particularly, the transit line is formed by a common stator thereof and each carrier present comprises a translator thereof movable independently of the translators of other carriers with respect to the stator thereof. In this way, the carriers can be independently controlled and positioned.

In a general sense, the invention also relates to a method for post-processing an encapsulated integrated circuit, comprising moving the encapsulated integrated circuit between a first receipt location and a first release location on a first carrier, taking off an encapsulated integrated circuit at the first release location from the first carrier carrying out on the encapsulated electrical circuit at least one post-processing device selected from the group of a punching or trimming device for shortening connection pins of the integrated circuit, a bending device for bending connection pins of the integrated circuit or a punching device for removing a lead frame of the integrated circuit dispensing an encapsulated integrated circuit at a second receipt location to a second carrier, moving the encapsulated integrated circuits with the second independently movable carrier between the second receipt location and a second release location, where the first release location and the second receipt location are at least substantially coincident, at least one post-processing device selected from the group of shortening connecting pins of the integrated circuit, bending connecting pins of the integrated circuit or removing a lead frame of the integrated circuit.

It is a further object of the present invention to provide a device and method for post-processing of encapsulated integrated circuits, in particular encapsulated integrated circuits of power electronics, such as those for use in electric cars.

For this purpose, the invention proposes a device for post processing of already encapsulated integrated circuits, comprising a transit line, extending from an input location in a feed direction along at least one post processing device for post processing of encapsulated integrated circuits to an output location, for moving the encapsulated integrated circuits across the transit line, at least one post-processing device, chosen from the group of a punching or trimming device for shortening integrated circuit connection pins, a bending device for bending integrated circuit connection pins or a punching device for removing a lead frame from the integrated circuit at least one transfer device, for removing an encapsulated integrated circuit from the transit line and feeding it in a direction with a directional component transverse to the transit direction, in particular parallel to a surface of the transit device to the at least one post-processing device from the encapsulated integrated circuit withdrawing from the at least one post-processing device the post-processed encapsulated integrated circuit, returning the post-processed encapsulated integrated circuit to the transit line, wherein the at least one post-processing device is located outside (e.g. adjacent to or above, but not on or in) the transit line.

Because the at least one post-processing device is located outside the transit line, the transit line places no or at least fewer restrictions on the input height, post-processing speed and issues such as the orientation of supplied encapsulated integrated circuits. The removal of the encapsulated integrated circuits from the transit line provides the possibility of using arbitrary post-processing devices and, if more than one post-processing device is used, of allowing asynchronous (step-by-step or non-step) feeding of encapsulated integrated circuits.

Because finishing takes place outside the transit line, no requirements need to be imposed on the post-processing facility with regard to being able to fit within restrictions of the transit line. Also, if there are several finishing facilities, it is easier to skip one post-processing facility. Furthermore, the conveyor line is not obstructed and thus not limited in height by finishing devices placed on it, as is usual according to the state of the art. A further advantage is that cut-outs or off-cuts that occur during a finishing operation are not created above the feedthrough, so they can be disposed of better and more efficiently, preferably for recycling.

Preferably, the at least one transfer device is arranged to move at least for at least and certain distance with the transit line during the removal from the transit line of an encapsulated integrated circuit and/or during the return to the transit line of an encapsulated integrated circuit. This eliminates the need to match the speed of the transit line to the finishing speed of the finishing device, or to pass through stepwise while having to match the speed to the slowest finishing device.

The at least one transfer device may further be arranged to turn a product upside down before feeding it to a finishing device; and/or after feeding it to a finishing device; and/or between removing an encapsulated integrated circuit from the transit line and returning the finished encapsulated integrated circuit to the transit line. This allows for more complex post-processing operations, such as bending connecting pins in two different (opposite) directions, or post-processing an encapsulated integrated circuit on multiple sides.

In a further embodiment, the device according to the invention comprises at least one optical inspection device, such as a camera, positioned such that it has a view of integrated circuits moved across the transit line and/or integrated circuits to be supplied to a finishing device and/or circuits received from a finishing device.

To this end, the at least one inspection device may preferably be positioned such that it has a view of a location where integrated circuits are passed before or after and preferably both before and after a post-processing step, in particular a location above the transit line at the level of the at least one post-processing device.

By viewing the integrated circuits before and after a post-processing step, it is possible to see for each post-processing step (or part thereof) whether this post-processing was carried out in the intended manner. When the integrated circuits are taken off the transit line by a transfer device and also returned to the same position there, such a position offers the possibility of performing a visual check on the integrated circuit both before and after the post-processing step.

For this purpose, the inspection device may preferably be positioned above the transit device at a location where the transfer device removes the integrated circuits from the transit line and/or a location where the transfer device feeds the integrated circuits to the at least one post-processing device and/or a location where the transfer device withdraws the integrated circuits from the at least one post-processing device and/or a location where the transfer device returns the integrated circuits to the transit line.

In a further embodiment, the at least one finishing device comprises a pressing device equipped with a servo motor to power the pressing device. The use of a servo motor has the advantage over the usual mostly pneumatically-powered press equipment that it is simpler and more accurate to operate, and that an electric power supply is easier to reprocess than a pneumatic one.

In a further embodiment, the device comprises sensors for measuring current and/or voltage through and across the servo motor, respectively. Current and/or voltage meters are relatively easy to fit, do not necessarily need to be fitted in close proximity to the respective servo motor and can provide a very accurate measurement result. A combination of a current and voltage meter allows an instantaneous power to be determined.

These measured values are particularly useful if the device is equipped with a protection device, arranged for comparing a measured current and/or voltage value through or across the servo motor with an expected current and/or voltage value and taking a safety measure, such as stopping a movement, when the measured current and/or voltage value differs from the expected current and/or voltage value by more than a threshold value. A deviation of the current or voltage from an expected value is usually an indication of an irregularity during the post-processing process, such as a blockage due to or precisely the absence of an integrated circuit.

In a preferred embodiment, also the device according to this embodiment of the invention is provided with at least a first carrier independently movable across the transit line, arranged for moving the encapsulated integrated circuits across the transit line between a first receipt location on the transit line and a first release location on the transit line; at least one second carrier independently movable across the transit line and arranged to move the encapsulated integrated circuits across the transit line between a second receipt location on the transit line and a second release location on the transit line, where the first release location and the second pick-up location are at least substantially coincident; and at least one finishing device, located at the level of the first release location.

The invention also relates to a method for post-processing an encapsulated integrated circuit, comprising moving the encapsulated integrated circuit over a transit line, removing an encapsulated integrated circuit from the transit line, feeding the encapsulated integrated circuit to the at least one post-processing device, performing at least one post-processing operation on the encapsulated integrated circuit chosen from the group of shortening connection pins of the integrated circuit bending connecting pins of the integrated circuit or removing a lead frame of the integrated circuit and withdrawing from the at least one post-processing device the post-processed non-integrated circuit and returning the post-processed non-integrated circuit to the transit line, wherein feeding the non-integrated circuit to the at least one post-processing device comprises feeding the post-processed non-integrated circuit outside the transit device to the post-processing device.

The method may further comprise optically inspecting the encapsulated integrated circuits at a location where integrated circuits are passed both before and after a post-processing step, in particular a location above the transit line at the level of the at least one post-processing device.

In yet a further embodiment, the method of operation comprises comparing a measured current and/or voltage value through or across a servo motor of the finishing device with an expected current and/or voltage value and taking a safety measure, such as stopping a movement, when the measured current and/or voltage value differs from the expected current and/or voltage value by more than a threshold value. The invention will now be explained using the following figures, wherein:

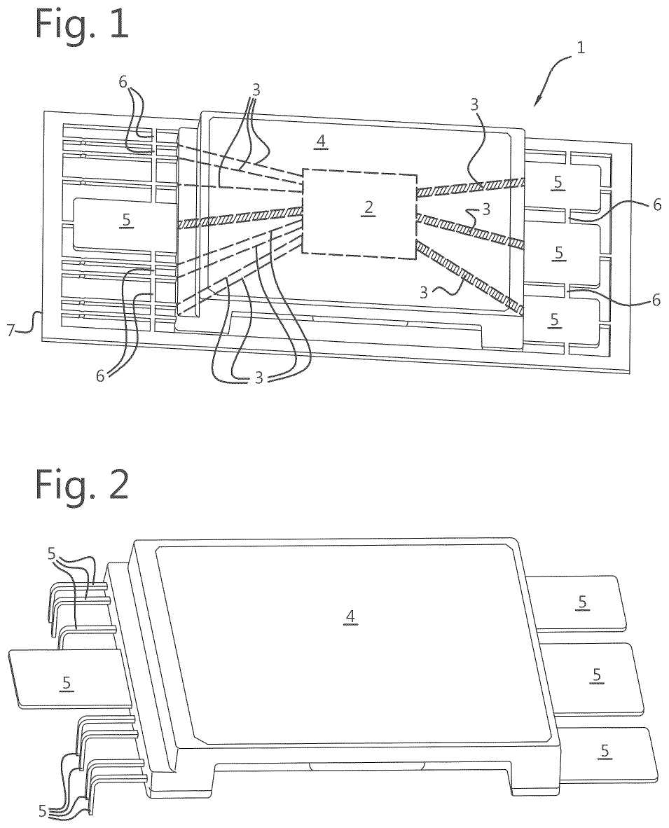

FIG. 1 shows a partially open-encapsulated integrated post-processable electronic circuit;

FIG. 2 shows a post-processed encapsulated integrated electronic circuit;

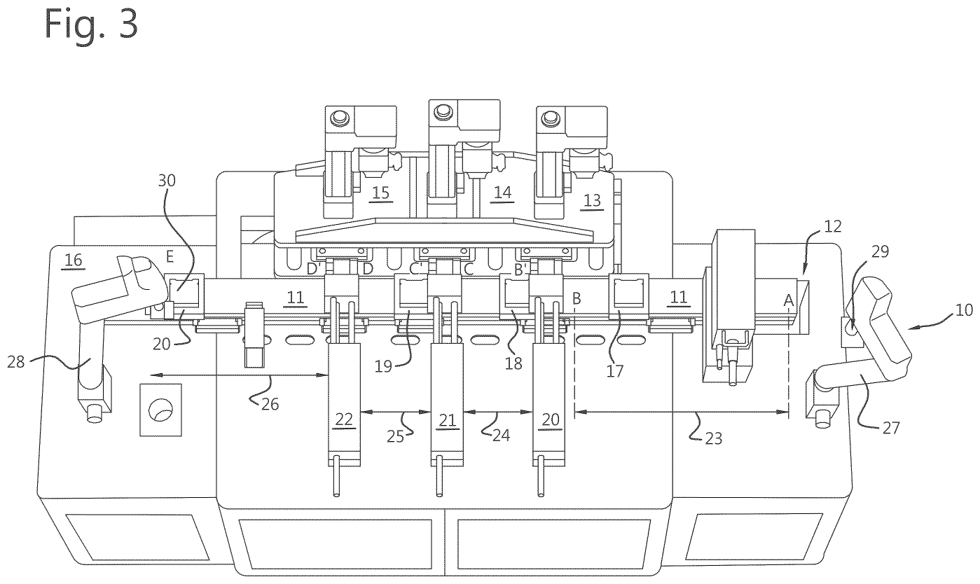

FIG. 3 shows a schematic of a device according to the invention;

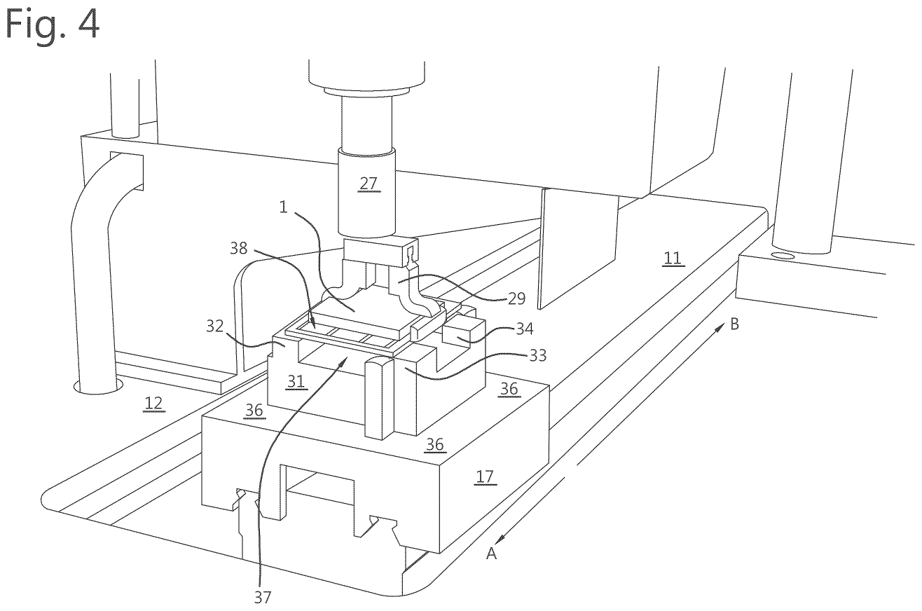

FIG. 4 shows a product carrier tray for carrying an integrated electronic circuit;

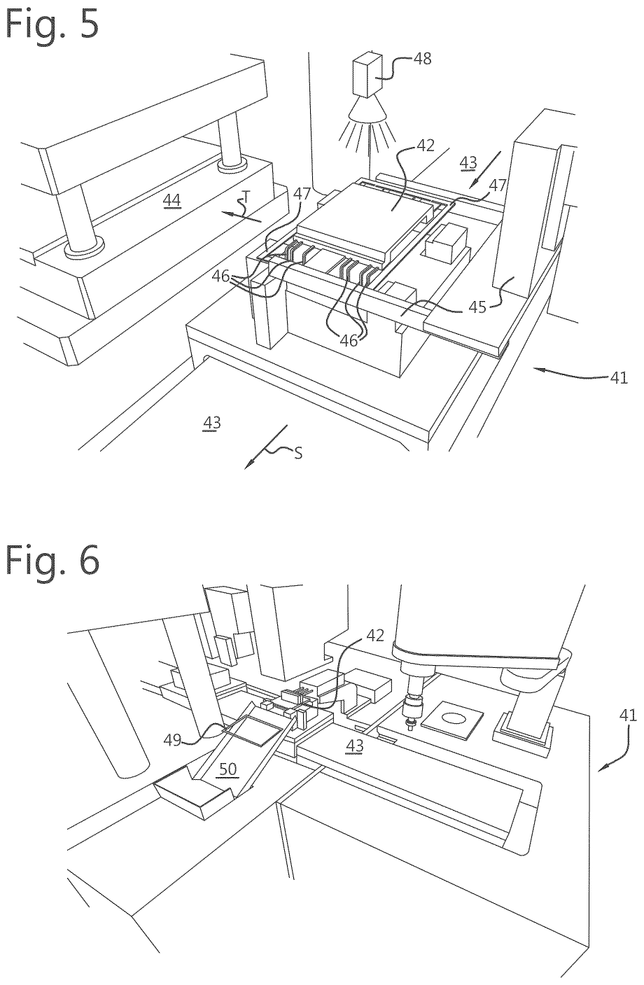

FIG. 5 shows a first detail of a device according to the invention; and

FIG. 6 shows a second detail of a device according to the invention.

Figure shows 1 an encapsulated integrated post-processable electronic circuit 1. The circuit comprises an electronic circuit 2 mounted on a wafer, which is connected to external terminal pins 5 by means of internal wiring 3 present within a housing 4. The external terminal pins are interconnected with connections 6 that serve for mutual stability during the manufacturing process but should be removed before use. The external connection pins 5 and the interconnections 6 are located on and within a lead frame 7 that is used in the manufacturing and post-processing of the encapsulated integrated electronic circuit 1 but should be removed before use.

FIG. 2 shows the encapsulated integrated electronic circuit after it has been post-processed. The through connections 6 have been removed by punching (trimming), the lead frame has been removed and part of the connection pins 5 have been bent (forming).

FIG. 3 shows a device according to the invention for post-processing of encapsulated integrated circuits, comprising a transit line (linear guide) 11 extending from an input location 12 along three post-processing devices 13, 14, 15 for post-processing of encapsulated integrated circuits to an output location 16, a four independently movable carriers 17, 18, 19 across the transit line 11, 20 each arranged for moving the encapsulated integrated circuits across the transit line 11 between a respective first receipt location (A, B′, C′, D′) on the transit line 11 and a first release location (B, C, D, E) on the transit line 11, wherein respective first release locations and second receipt locations of successive carriers are at least substantially coincident (B-B′, C-C′, D-D′). The post-processing devices comprise a first punching or trimming device 13 for shortening connection pins of the integrated circuit, a bending device 14 for bending connection pins of the integrated circuit and a punching device 15 for removing a lead frame of the integrated circuit. The device further comprises a trio of transfer devices 20, 21, 22, each for taking a first release location (B, C, D) from a first carrier of an encapsulated integrated circuit, passing the encapsulated electrical circuit through a post-processing device; and releasing an encapsulated integrated circuit at a second receipt location (B′, C′, D′) to the second carrier. The carriers 17, 18, 19, 20 each shuttle up and down a trajectory 23, 24, 25, 26, respectively. The device further comprises a gripper 29 movable with a robotic arm 27, for gripping at the input location 12 and delivering to the device a from a housing integrated circuit to be finished, and an output device with a robotic arm 28, for outputting at the output location 16 from the device 1 a finished housing integrated circuit with a gripper 30.

FIG. 4 shows a product carrier tray 31 affixed to a carrier 17, which tray is provided with spacers 32. 33, 34, 35 for carrying an encapsulated integrated circuit 1 remotely from a carrier surface 36 that it is grippable on at least one side at top and bottom 37, 38 for an input, output or transfer device (27, 29).

FIG. 5 shows a device 41 for post-processing of encapsulated integrated circuits 42, comprising a transit line 43 extending along at least one post-processing device 44 for post-processing of encapsulated integrated circuits 42 and is arranged for moving the encapsulated integrated circuits 42 across the transit line 43 in a direction of transit S and at least one finishing device 44 selected from the group consisting of a punching or trimming device for shortening connection pins 46 of the integrated circuit 42, a bending device for bending connection pins 6 of the integrated circuit or a punching device for removing a lead frame 47 of the integrated circuit 42 and a transfer device 45 for withdrawing an encapsulated integrated circuit 42 from the transit line 43 and feeding the encapsulated integrated circuit 42 in a direction with a directional component T perpendicular to the transit direction S to the at least one finishing device 44, withdrawing the encapsulated integrated circuit 42 from the at least one finishing device 44, returning the encapsulated integrated circuit 42 to the transit line 43, where the at least one finishing device 44 is located outside, in this case adjacent to, the transit line 42.

The transfer device 45 is arranged to move at least for at least and specified distance in direction S with the transit line 43 during removal from the transit line 43 of an encapsulated integrated circuit 42; and/or during return to the transit line 43 of an encapsulated integrated circuit 42.

The device further comprises at least one optical inspection device 48 formed by a camera positioned so as to have a view of integrated circuits 42 displaced across the transit line 43 and integrated circuits 42 to be supplied to the finishing device 45 and circuits 42 received from the finishing device 45. In this way, one optical inspection device 48 can identify any faults during various post-processing stages of the integrated circuits 42. This would not be possible if the post-processing device 44 was located at or above the throughput device 42 as is common in the prior art. The inspection device 48 is positioned above the throughput device 43 at a location where the transfer device 45 removes the integrated circuits 42 from the transit line 43 and feeds the integrated circuits 42 to the at least one post-processing device 44 and where the transfer device 45 takes back the integrated circuits 42 from the post-processing device 44 and a location where the transfer device 45 returns the integrated circuits 42 to the transit line 43.

FIG. 6 shows a second schematic view of a portion of a device 41 according to the invention in which it can be seen that a punched-out lead frame 49 created during a finishing operation is discharged into a discharge device 50 located adjacent to the transit device 43.

The examples given above serve only to clarify the invention and in no way limit the scope of protection as defined in the following claims.

1. A device for post-processing of encapsulated integrated circuits, comprising:
a transit line extending from an input location past at least one post-processing facility for post-processing of encapsulated integrated circuits to an output location,
at least one first carrier, movable over the transit line, configured for: moving the encapsulated integrated circuits over the transit line between a first receipt location on the transit line and a first release location on the transit line;
at least one second carrier movable over the transit line, configured for:
moving the encapsulated integrated circuits across the transit line between a second receipt location on the transit line and a second release location on the transit line;
at least one post-processing facility, at the level of the first release location and selected from the group of:
a punching or trimming device for shortening connection pins of the integrated circuit,
a bending device for bending connecting pins of the integrated circuit or
a punching device for removing a lead frame from the integrated circuit;
at least one transfer device, for:
taking an encapsulated integrated circuit off the first carrier at the first release location;
feeding the encapsulated electrical circuit through the first post-processing device; and
delivering the encapsulated integrated circuit, to the second carrier at the second receipt location;
wherein characterized in that
the first and second carriers are independently from each other movable over the transit line.

2. The device according to claim 1, where the first and second carriers are arranged for moving one encapsulated integrated circuit at a time each.

3. The device according to claim 1, wherein the first carrier is arranged to shuttle back and forth between a first receipt location on the transit line and a first release location on the transit line and the second carrier is arranged to shuttle back and forth between a second receipt location on the transit line and a second release location on the transit line.

4. The device according to claim 1, including:
at least one third carrier moveable independently of the first and second carriers across the transit line, for moving the encapsulated integrated circuits across the transit line between a third receipt location on the transit line and a third release location on the transit line, with the second release location and the third receipt location at least substantially coinciding;
a second post-processing facility, at the level of the second release location and selected from the group of:
a punching or triminriching device for shortening connection pins of the integrated circuit,
a bending device for bending connecting pins of the integrated circuit or
a punching device for removing a lead frame from the integrated circuit;
A second transfer device, for:
taking an encapsulated integrated circuit off the second carrier at the second release location;
feeding the encapsulated electrical circuit through the second post-processing device; and
transferring the encapsulated integrated circuit to the third carrier at the third receipt location.

5. The device according to claim 1, cascaded with similar or identical device.

6. The device according to claim 1, comprising an infeed device, comprising in particular a gripper movable by means of a robotic arm, for engaging an integrated circuit to be finished at the input location and feeding it to the device for post-processing of encapsulated integrated circuits.

7. The device according to claim 1, comprising an output device, for outputting a finished enclosed integrated circuit at the output location from the device for post-processing of encapsulated integrated circuits.

8. The device according to claim 1, comprising a product carrier tray mounted on at least one of the carriers or integrally provided therewith, which tray is provided with a spacer for carrying an encapsulated integrated circuit at a distance from a carrier surface such that it can be gripped on at least one side at the top and bottom for an import, export or transfer device.

9. The device according to claim 8, wherein the carrier is arranged for carrying the encapsulated integrated circuit on a lead frame.

10. The device according to claim 1, equipped for sorting out punching or trimming waste.

11. The device according to claim 1, wherein the transit line comprises a linear motor.

12. A device for post-processing of encapsulated integrated circuits, comprising:
a transit line, extending from an input location past at least one post-processing facility for the post-processing of encapsulated integrated circuits to an output location, for:
moving across the transit line of encapsulated integrated circuits;
at least one finishing device chosen from the group of:
a punching or trimming device for shortening connection pins of the integrated circuit,
a bending device for bending connection pins of the integrated circuit or
a punching device for removing a lead frame from the integrated circuit;
at least one transfer device, for:
taking an encapsulated integrated circuit off the first carrier at the first release location;
feeding the encapsulated electrical circuit through the first post-processing device; and
delivering the encapsulated integrated circuit, to the second carrier at the second receipt location;
wherein
the at least one finishing device is located outside and therefore not on or in the transit line.

13. The device according to claim 12, wherein the at least one transfer device is arranged to move at least for a certain distance along the transit line during:
taking an encapsulated integrated circuit off the first carrier at the first release location; and/or
delivering the encapsulated integrated circuit, to the second carrier at the second receipt location.

14. The device according to claim 12, wherein the at least one transfer device is arranged to turn a product upside down:
before feeding it to a post-processing facility; and/or
after it has been fed to a post-processing facility; and/or
between:
taking encapsulated integrated circuit from the transit line; and
putting the finished encapsulated integrated circuit back on the transit line.

15. A method for post-processing an encapsulated integrated circuit, comprising:
moving encapsulated integrated circuits on a first carrier between a first receipt location and a first release location;
taking an encapsulated integrated circuit at the first release location off the first carrier;
post processing the encapsulated integrated circuit by means of:
shortening connection pins of the integrated circuit,
bending connecting pins of the integrated circuit or
removing a lead frame from the integrated circuit;
delivering an encapsulated integrated circuit at a second receipt location to a second carrier;
independently moving the encapsulated integrated circuits between the second receiving site and a second dispensing site, where the first release location and the second receipt location at least essentially coincide.
